(19) United States
(12) Patent Application Publication
(10) Pub. No.: US 2007/0217469 A1
(43) Pub. Date: Sep. 20, 2007

(54) Laser diode stack side-pumped solid state laser

(75) Inventors: Mark Joseph DeFranza, Ridgefield, WA (US); David Clifford Dawson, Brush Prairie, WA (US); Jason Nathaniel Farmer, Vancouver, WA (US)

Correspondence Address: Patent Law Office Of David G. Beck, P. O. Box 1146, Mill Valley, CA, 94942, US

(73) Assignee: nLight Photonics Corporation, Vancouver, WA (US)

(21) Appl. No.: 11/417,726

(22) Filed: May 4, 2006

Related U.S. Application Data
(63) Continuation-in-part of application No. 11/384,940, filed on Mar. 20, 2006.

(51) Int. Cl. H01S 3/04; H01S 5/00

(52) U.S. Cl. 372/50.12; 372/36

(57) ABSTRACT

A side-pumped solid state laser utilizing a laser diode stack of laser diode submount assemblies is provided. The laser gain medium of the solid state laser is contained within a laser cavity defined by a pair of reflective elements. Each laser diode submount assembly includes a submount to which one or more laser diodes are attached. The radiation-emitting active layer of each laser diode is positioned substantially parallel to the mounting surfaces of the submount, causing the fast axis of each laser diode's output beam to be substantially orthogonal to the submount mounting surfaces. The laser diodes can be of one wavelength or multiple wavelengths. Preferably the submount has a high thermal conductivity and a CTE that is matched to that of the laser diode. On top of the submount, adjacent to the laser diode, is a spacer. The laser diode stack is formed by mechanically coupling the bottom surface of each submount to the spacer of an adjacent submount assembly. Preferably the laser diode stack is thermally coupled to a cooling block.

### CROSS-REFERENCE TO RELATED APPLICATION

This application is a continuation-in-part of U.S. patent application Ser. No. 11/384,940, filed Mar. 20, 2006, the disclosure of which is incorporated herein by reference for any and all purposes.

### FIELD OF THE INVENTION

The present invention relates generally to semiconductor lasers and, more particularly, to a side-pumped solid state laser utilizing a laser diode stack as the pump source.

### BACKGROUND OF THE INVENTION

High power laser diodes, due to their size, efficiency and wavelength range, are well suited for pumping high power solid state lasers. In such laser systems the output from one or more laser diodes is coupled into a laser gain medium, the gain medium contained within a laser cavity defined by a pair of mirrors or reflective coatings disposed at either end of the medium. The laser diode output may be coupled into either an end surface of the gain medium, creating an end-pumped laser, or into one or more side surfaces of the gain medium, creating a side-pumped laser. End-pumped lasers are typically of lower power than side-pumped lasers due to the difficulty in coupling the output from multiple laser diodes into the relatively small end surface of the gain medium.

A variety of techniques have been developed to try and improve the coupling efficiency of the laser diode or diodes to the gain medium. For example, in some side-pumped configurations a reflector is disposed on the opposite side of the gain medium from the laser diode, thereby causing the output from the laser diode to pass through the gain medium at least twice; once during the initial pass and again as a reflected beam. In an alternate configuration, multiple laser diodes are directed at different sides of the gain medium. Although this approach may not optimize coupling efficiency, it typically results in greater output power from the gain medium due to the increased input energy. In yet another alternate configuration, one or more optical elements are interposed between the output of the laser diode and the gain medium in order to increase the solid angle of light collected from the laser diode and reduce the Fresnel reflection losses, thereby improving coupling efficiency.

Regardless of the configuration of the laser system, heat dissipation is a critical issue for several reasons. First, heat build-up within the gain medium, especially in localized regions, can lead to instabilities in the output beam. Second, heat build-up in the laser diode can lead to reduced operating efficiency, wavelength shifts and eventually catastrophic failure. Third, both excessive temperature and thermal cycling can lead to component misalignment and in some instances, component de-bonding (for example, the cylindrical lenses attached to the output facets of the laser diodes in some configurations). Heat dissipation systems, for example those that pump coolant through passages within the various system mounting structures, add significantly to system complexity, weight and cost, while not eliminating all of the issues that result from thermal cycling.

Accordingly, what is needed in the art is a system that can be used to efficiently couple energy from a laser diode array into a laser gain medium, thereby minimizing excessive heat build-up and the effects of thermal cycling. The present invention provides such a system.

### SUMMARY OF THE INVENTION

The present invention provides a side-pumped solid state laser utilizing a laser diode stack of laser diode submount assemblies. The laser gain medium of the solid state laser is contained within a laser cavity defined by a pair of reflective elements. Each laser diode submount assembly includes a submount to which one or more laser diodes are attached. The radiation-emitting active layer of each laser diode is positioned substantially parallel to the mounting surfaces of the submount, causing the fast axis of each laser diode's output beam to be substantially orthogonal to the submount mounting surfaces. Exemplary laser diodes include single mode single emitter laser diodes, broad area multi-mode single emitter laser diodes, and multiple single emitters fabricated on either a single substrate or on multiple substrates. The laser diodes can be of one wavelength or multiple wavelengths. Preferably the submount has a high thermal conductivity and a CTE that is matched to that of the laser diode. In an exemplary embodiment the submount is fabricated from 90/10 tungsten copper and the laser diode is attached to the submount with a gold-tin solder. An electrically isolating pad is attached to the same surface of the submount as the laser diode. A metallization layer is deposited onto the outermost surface of the electrically isolating pad, to which an electrical contact pad is bonded. Electrical interconnects, such as wire or ribbon interconnects, connect the single emitter laser diode to the metallization layer. Preferably the laser diode stack is formed by electrically and mechanically bonding together the bottom surface of each submount to the electrical contact pad of an adjacent submount assembly, for example using a silver-tin solder.

To provide package cooling, the laser diode stack is thermally coupled to a cooling block, the cooling block preferably including a slotted region into which the laser diode stack fits. In at least one preferred embodiment of the invention, thermally conductive and electrically isolating members are first bonded to the bottom and side surfaces of each submount and then bonded to the cooling block, the members being interposed between the laser diode stack and the cooling block. Preferably the cooling block is comprised of a pair of members, thus insuring good thermal coupling between the laser diode stack and the cooling block.

In at least one embodiment of the invention, coupling optics are interposed between the laser gain medium and the laser diode stack.

A further understanding of the nature and advantages of the present invention may be realized by reference to the remaining portions of the specification and the drawings.

### BRIEF DESCRIPTION OF THE DRAWINGS

FIG. 1 is an illustration of a side-pumped solid state laser in accordance with the invention;

FIG. 2 is an illustration of the elliptical output from a typical laser bar according to the prior art;

FIG. 3 is a side view of a side-pumped solid state laser using the laser bar of FIG. 2;

FIG. 4 is an illustration of the elliptical output from a laser stack for use with the invention;

FIG. 5 is a side view of a side-pumped solid state laser using the laser stack of FIG. 4;

FIG. 6 shows an end view of a laser diode stack in accordance with the invention, the stack including ten submount assemblies and in which each assembly includes three emitters;

FIG. 7 is a perspective view of laser diode submount assembly in accordance with the invention;

FIG. 8 is a perspective view of a laser diode stack comprised of multiple submount assemblies;

FIG. 9 is a perspective view of the laser diode stack of FIG. 8 along with an electrically isolating backplane member;

FIG. 10 is a perspective view of the laser diode stack of FIG. 9 along with electrically isolating side frame members and a pair of contact assemblies; and

FIG. 11 is a perspective view of the laser diode stack of FIG. 10 attached to a cooling block.

### DESCRIPTION OF THE SPECIFIC EMBODIMENTS

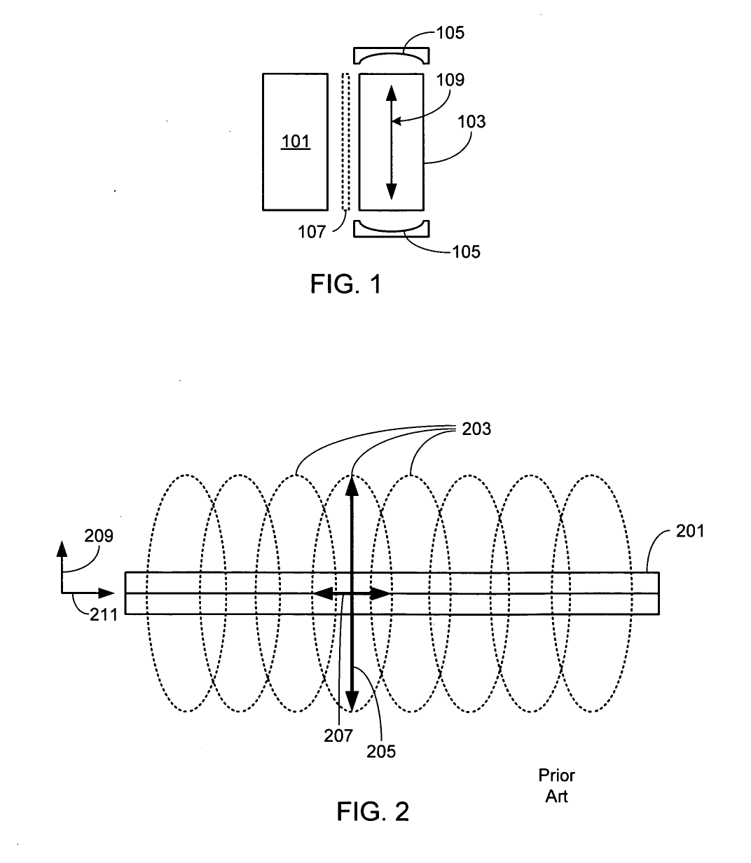

FIG. 1 is an illustration of a laser system in accordance with the invention. As shown, the system includes at least one laser diode stack 101, the laser gain medium 103, and laser cavity mirrors 105. It will be appreciated that the laser gain medium can be any appropriately doped glass or crystal of any shape, and that cylindrically-shaped (i.e., rod shaped) and rectangularly-shaped (i.e., slab shaped) medium are but two exemplary shapes. A variety of suitable materials, as well as a variety of suitable cavity configurations, are well know by those of skill in the art and will therefore not be described in detail herein. Although the system may include a coupling optic (e.g., a lens 107 shown in phantom) between laser diode stack 101 and laser gain medium 103, in the preferred embodiment there is no coupling optic as discussed in detail below.

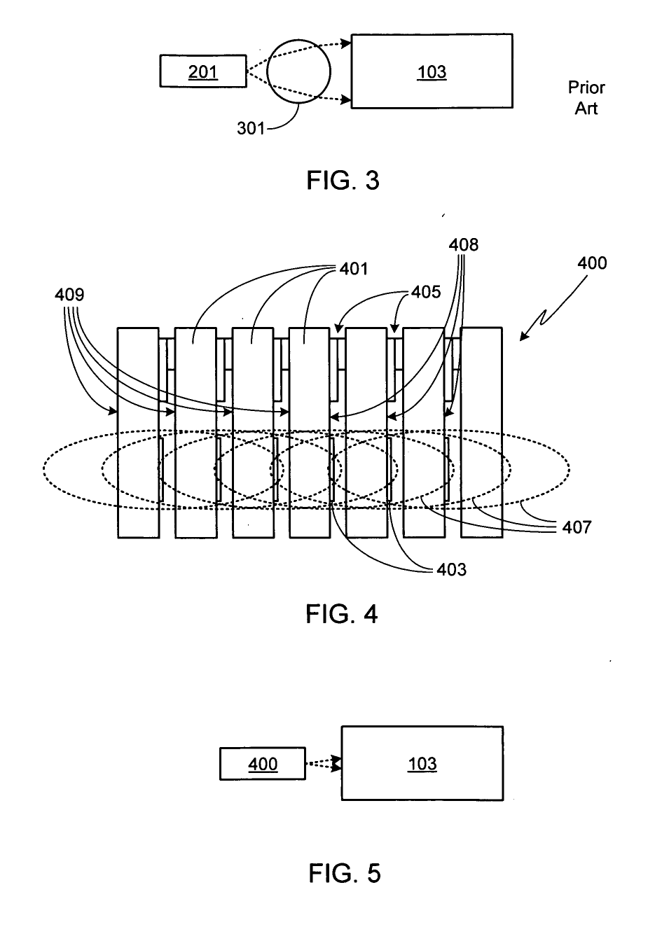

In order to achieve the desired system performance, specifically increasing the solid angle of light collected by gain medium 103 from laser diode stack 101 while improving upon the thermal qualities of the system, the present invention does not utilize a laser bar for laser diode 101. Rather, the invention uses a stack of emitters as described in further detail below. An advantage of such a stack is illustrated in FIGS. 2-5. FIG. 2 shows the end view of a laser bar 201 such as that typically used for laser pumping or other high power laser diode applications. As shown, each emitter within the laser bar's active layer emits an elliptical beam 203 with the fast axis 205 orthogonal to the diode's active layer and the slow axis 207 parallel to the diode's active layer. Thus the combination of the individual output beams from laser bar 201 creates an output that is rapidly diverging along axis 209 and is on the order of 1 centimeter, the length of a laser bar, along axis 211. Note that for illustration clarity, only 8 beams 203 are shown in FIG. 2 although it will be appreciated that a typical laser bar includes many more emitters. FIG. 3 is a side view of a side-pumped laser system, similar to that shown in FIG. 1 except for the use of laser bar 201. The active layer of laser bar 201 is substantially parallel to the longitudinal axis 109 of laser gain medium 103 which, in FIG. 3, is orthogonal to the plane of the figure. As shown, a coupling optic 301 is used to compensate for the high divergence of the beam perpendicular to the diode junction, thus achieving improved mode overlap. It should also be appreciated that unless the length of gain medium 103 is a multiple of 1 centimeter, the standard length of a laser bar, the mismatch between the gain medium and the laser bar results in inefficient coupling of the output of the laser bar into the medium.

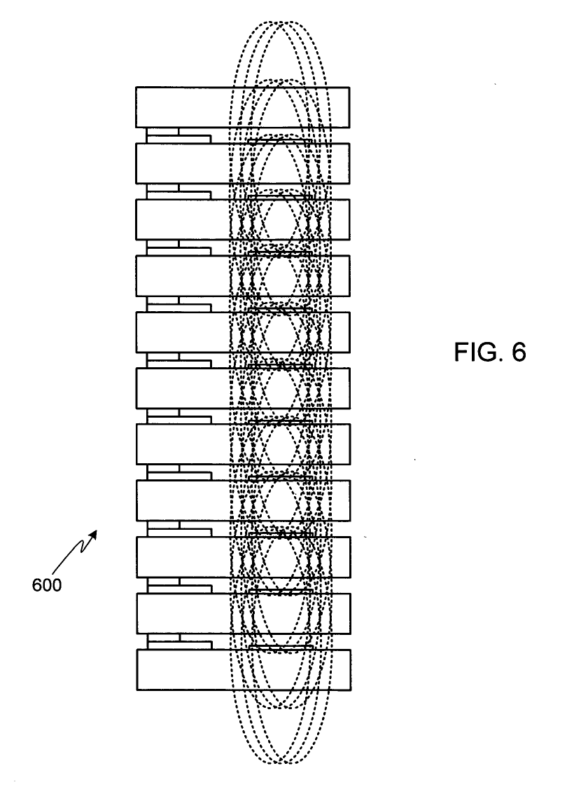

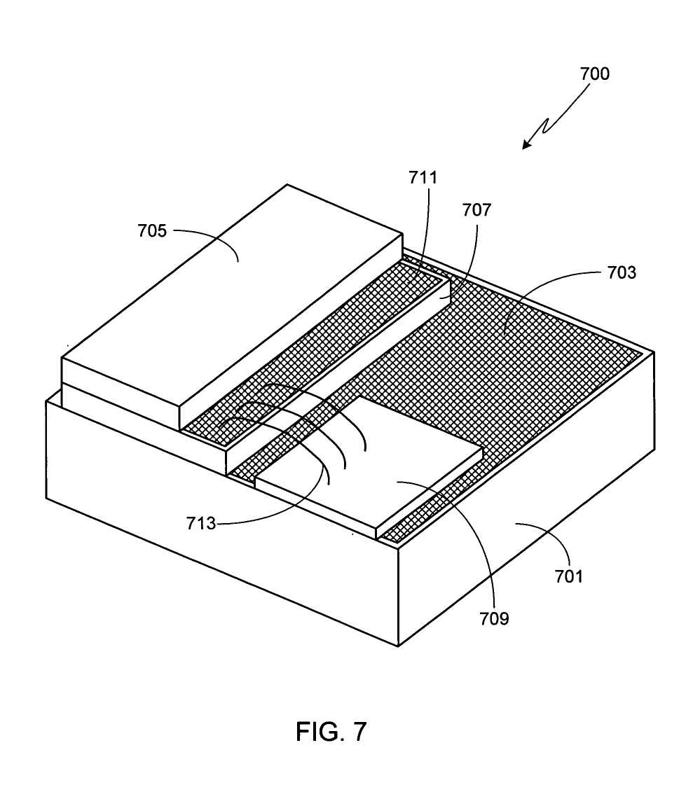

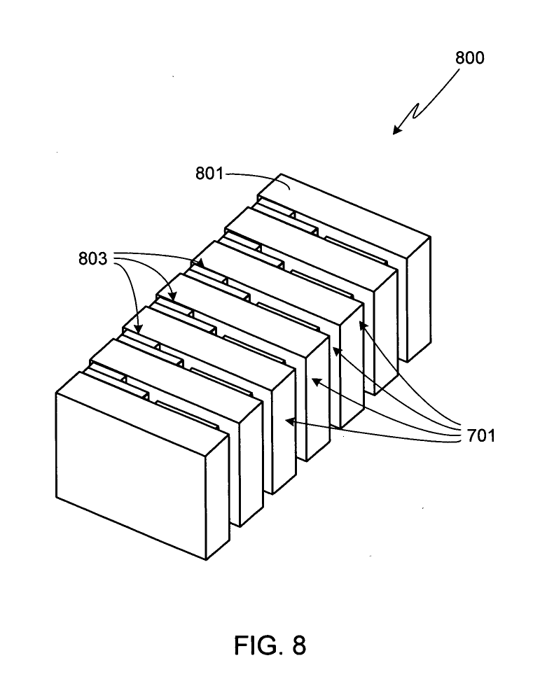

FIG. 4 is an end view of the output from a laser diode stack 400 in accordance with the invention. In this figure, and as described in detail below, the laser diode stack 400 includes a plurality of laser diode submounts 401, each of which includes at least one diode laser 403 and one or more spacers 405. In marked contrast to the output beam from laser bar 201, the fast axis of the output beams 407 from the laser diode stack subassemblies are co-aligned (e.g., the fast axis of each output beam 407 is substantially orthogonal to the submount mounting surfaces 408 and 409). As illustrated in FIG. 5, by reversing the fast and slow axes relative to a laser bar (e.g., bar 201 of FIG. 2), the fast axis of each output beam of laser diode stack 400 is substantially parallel to the longitudinal axis 109 of the gain medium resulting in efficient coupling of the pump radiation into the gain medium 103, even without the use of coupling optic 301. Additionally the laser diode stack can be designed to efficiently fill the gain medium regardless of its size, both through the selection of an appropriate number of submount assemblies and by the number of laser diode emitters located on each assembly. For example, laser diode stack 600 shown in FIG. 6 includes 10 subassemblies with each laser diode having three emitters. Additionally, the present invention provides improved heat dissipation, the ability to vary the wavelength, and individual laser diode addressability.

In addition to providing a pump laser that can be sized to provide an efficient overlap of the mode of the laser diode/array and the mode volume of the gain medium, the present invention also provides a means of compensating for temperature induced variations in the pump wavelength. As is well known by those of skill in the art, since the output wavelength of a laser diode varies with temperature, the pumping efficiency may vary as the system changes temperature and the pump wavelength varies from the optimal wavelength. As a result of this variation, the output of a conventional solid state laser may also vary with temperature. The laser diode stack of the present invention, however, can be designed to operate at multiple wavelengths simply by including emitters of different wavelengths. Thus, for example, one group of emitters can be the primary pump source at the initial temperature, then a second group of emitters can become the primary pump source as the system temperature increases with time, then a third group of emitters can become the primary pump source as the temperature increases further, etc. These wavelength-grouped emitters are preferably spread throughout the entire laser diode stack, thus insuring that the entire volume of the gain medium is efficiently pumped. In a preferred configuration, the emitters are grouped by submount. For example, a two wavelength stack would alternate submounts containing first and second wavelength emitters. In an alternate configuration, each submount includes multiple laser diode emitters, preferably on individual substrates, each operating at a different wavelength. It will be appreciated that there are a variety of possible configurations depending upon the number of desired wavelengths, the number of submount assemblies, and the number of emitters per submount assembly.

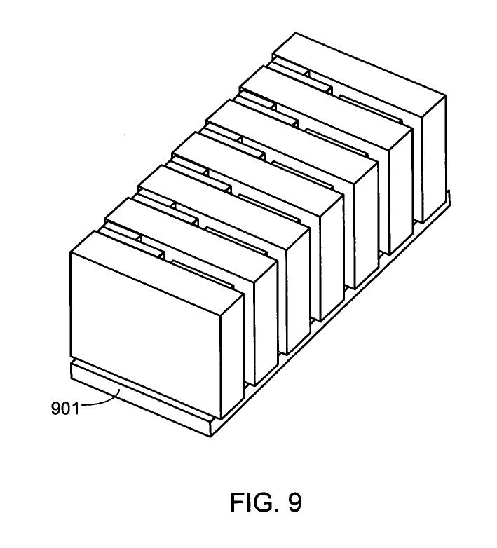

FIG. 7 is an illustration of a single laser diode submount assembly 700. To achieve the desired levels of performance and reliability, preferably submount 701 is comprised of a material with a high thermal conductivity and a CTE that is matched to that of the laser diode. Exemplary materials include copper tungsten, copper molybdenum, and a variety of matrix metal and carbon composites. In a preferred embodiment, a 90/10 tungsten copper alloy is used. On the upper surface of submount 701 is a layer 703 of a bonding solder. Solder layer 703 is preferably comprised of gold-tin, thus overcoming the reliability issues associated with the use of indium solder as a means of bonding the laser diode to the substrate.

On top of submount 701 is a spacer. In the preferred embodiment, the spacer is comprised of a first contact pad 705, preferably used as the N contact for the laser diode, and an electrically insulating isolator 707 interposed between contact pad 705 and submount 701. Preferably insulating isolator 707 is attached to submount 701 via solder layer 703. Preferably contact pad 705 is attached to isolator 707 using the same solder material as that of layer 703 (e.g., Au—Sn solder). Also mounted to submount 701 via solder layer 703 is a laser diode 709 positioned such that the radiation-emitting active layer of the laser is substantially parallel to the mounting surfaces of submount 701 (e.g., surfaces 408 and 409 of FIG. 4). Exemplary laser diodes include both single mode single emitter laser diodes and broad area multi-mode single emitter laser diodes. Additionally, multiple single emitters, either fabricated on individual substrates or on a single substrate, can be mounted to submount 701, thereby forming an array of single emitters on a single submount assembly. As previously noted, the submount assemblies of the invention do not utilize laser bars, both due to the size of laser bars (i.e., 1 centimeter) and their poor heat dissipation characteristics that result from close emitter packing. In this embodiment of the invention one contact of laser diode 709, preferably the P contact, is made via submount 701, while the second contact, preferably the N contact, is made using wire bonds, or ribbon bonds, which couple the laser diode to metallization layer 711. Representative wire bonds 713 are shown in FIG. 7.

After completion of submount assembly 700, preferably the laser diode or diodes 709 attached to the submount are tested. Early testing, i.e., prior to assembly of the entire laser diode stack, offers several advantages over testing after stack completion. First, it allows defective laser diodes to be identified prior to stack assembly, thus minimizing the risk of completing a stack assembly only to find that it does not meet specifications due to one or more defective laser diodes. Thus the present stack assembly improves on assembly fabrication efficiency, both in terms of time and materials. Second, early testing allows improved matching of the performance of the individual laser diodes within an assembly, for example providing a means of achieving improved wavelength matching between laser diodes or allowing laser diodes operating at different wavelengths to be grouped together in the desired order.

During the next series of steps the laser diode stack, which is comprised of a stack of laser diode submount assemblies 700, is fabricated. The perspective view of FIG. 8 shows a stack 800 comprised of six submount assemblies 700 along with an additional submount 801. Although laser diode stack 800 can be fabricated without additional submount 801, the inventors have found that it improves the mechanical reliability of the laser diode package. It will be appreciated that the laser diode stack can utilize fewer, or greater, numbers of submount assemblies 700 and that either horizontal or vertical stack assemblies can be fabricated.

In a preferred embodiment of the invention, laser diodes 709 are serially coupled together. In this embodiment the individual submount assemblies 700 are combined into a single assembly by bonding the upper surface of each contact pad 705 to a portion of the lower surface of the adjacent submount 701, submounts 701 being comprised of an electrically conductive material. Preferably solder 803 coupling contact pads 705 to submounts 701 has a lower melting temperature than the solder used to fabricate submount assembly 701, thus insuring that during this stage of assembly the reflow process used to combine the submount assemblies will not damage the individual assemblies. In a preferred embodiment of the invention, a silver-tin solder is used with a melting temperature lower than that of the Au—Sn solder preferably used for solder joint 803.

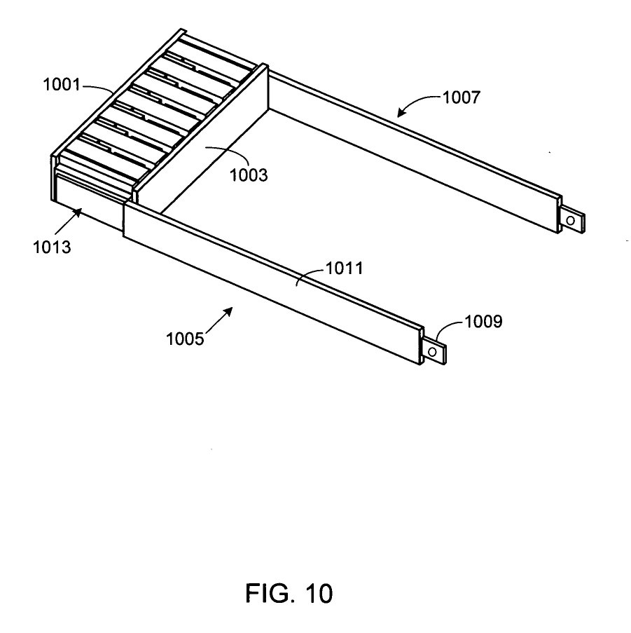

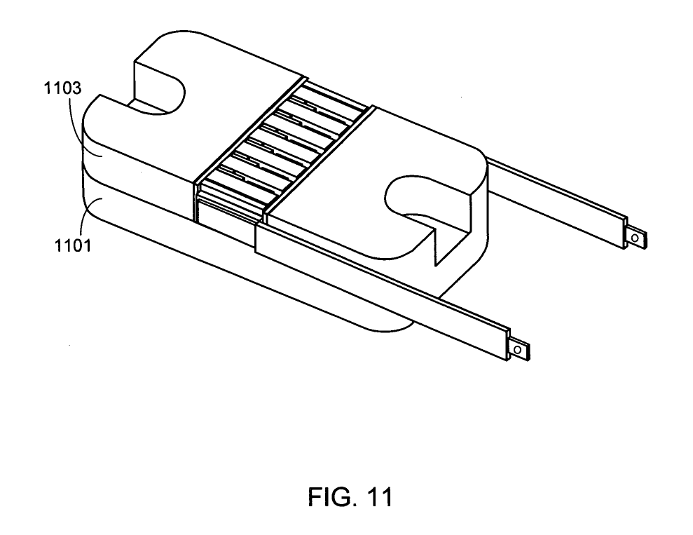

In the next series of processing steps, illustrated in FIGS. 9 and 10, an electrically isolating backplane member 901 as well as electrically isolating side frame members 1001 and 1003 are attached to the back surface and the side surfaces, respectively, of submounts 701. In the preferred embodiment members 901, 1001 and 1003 are fabricated from beryllium oxide, a material that is both thermally conductive and electrically isolating. It will be appreciated that other thermally conductive/electrically isolating materials, such as aluminum nitride, CVD diamond or silicon carbide, can be used for members 901, 1001 and 1003. Preferably the solder used to attach members 901, 1001 and 1003 to submounts 701 has a lower melting temperature than that used to couple together submount assemblies 701 (i.e., solder 803). Accordingly in at least one embodiment a tin-indium-silver solder is used.

In an alternate embodiment of the invention laser diodes 709 are not serially coupled together, rather they are coupled together in parallel, or they are individually addressable. Individual addressability allows a subset of the total number of laser diodes within the stack to be activated at any given time. In order to achieve individual addressability, or to couple the laser diodes together in a parallel fashion, the electrically conductive path between individual submount assemblies must be severed, for example using a pad 705 that is not electrically conductive, and/or using a submount 701 that is not electrically conductive, and/or placing an electrically isolating layer between submounts 701 and pads 705 within assembly 800. Parallel connections as well as individual laser diode connections can be made, for example, by coupling interconnect cables to metallization layers 703 and 711. Additionally one or more of members 901, 1001 and 1003 can be patterned with electrical conductors, thus providing convenient surfaces for the inclusion of circuit boards that can simplify the relatively complex wiring needed to provide individual laser diode addressability.

In the preferred package assembly process and assuming that the laser diode subassemblies are serially coupled together, the same mounting fixture that is used to attach side members 1001 and 1003 to submounts 701 is also used to attach contact assemblies 1005 and 1007 to the laser diode package. Preferably contact assemblies 1005 and 1007 are assembled in advance using a higher melting temperature solder such as a gold-tin solder. Each contact assembly 1005/1007 includes a wire 1009, covered with an insulator 1011 (e.g., Kapton), and a contact (or contact assembly) 1013.

In the preferred embodiment, the laser diode submount stack assembly, shown in FIGS. 9 and 10, is attached to a cooler body as illustrated in FIG. 11. Preferably the cooler body is comprised of two parts; a primary member 1101 and a secondary member 1103. The benefit of having two members 1101/1103 rather than a single slotted member is that it is easier to achieve a closer fit between the cooler body and the laser diode submount stack assembly, thus insuring more efficient heat transfer and thus assembly cooling. Preferably bottom member 901 and side members 1001 and 1003 are soldered to members 1101/1103 of the cooler body, thus insuring a mechanically robust assembly.

As will be understood by those familiar with the art, the present invention may be embodied in other specific forms without departing from the spirit or essential characteristics thereof. Accordingly, the disclosures and descriptions herein are intended to be illustrative, but not limiting, of the scope of the invention which is set forth in the following claims.

What is claimed is:

1. A side-pumped solid state laser comprising:
a plurality of laser diode submount assemblies, wherein each of said plurality of laser diode submount assemblies comprises:
a submount, said submount further comprising a first mounting surface and a second mounting surface;
at least one laser diode attached to a first portion of said first mounting surface of said submount, said at least one laser diode further comprising a radiation-emitting active layer substantially parallel to said first mounting surface of said submount, and wherein a fast axis corresponding to an output beam of said radiation-emitting active layer is substantially orthogonal to said first mounting surface of said submount; and
a spacer attached to a second portion of said first mounting surface of said submount;
means for mechanically coupling each laser diode submount assembly spacer to said second mounting surface of said submount of an adjacent laser diode submount assembly to form a laser diode stack; and
a laser gain medium mounted adjacent to said laser diode stack and positioned to receive said output beam of said radiation-emitting active layer of each submount assembly of said laser diode stack, wherein a longitudinal axis of said laser gain medium is substantially orthogonal to said first mounting surface of said submount of each submount assembly of said laser diode stack.

2. The side-pumped solid state laser of claim 1, further comprising a first reflective element and a second reflective element, wherein said first and second reflective elements form a laser cavity, wherein said laser gain medium is contained within said laser cavity.

3. The side-pumped solid state laser of claim 1, further comprising an coupling optic interposed between said laser gain medium and said laser diode stack.

4. The side-pumped solid state laser of claim 1, further comprising a cooling block in thermal communication with each submount of said plurality of laser diode submount assemblies.

5. The side-pumped solid state laser of claim 4, further comprising a backplane member interposed between a back surface of each submount of said plurality of laser diode submount assemblies and said cooling block.

6. The side-pumped solid state laser of claim 5, wherein said backplane member is comprised of an electrically isolating material.

7. The side-pumped solid state laser of claim 6, wherein said electrically isolating material is selected from the group consisting of aluminum nitride, beryllium oxide, CVD diamond and silicon carbide.

8. The side-pumped solid state laser of claim 4, further comprising a side frame member interposed between a side surface of each submount of said plurality of laser diode submount assemblies and said cooling block.

9. The side-pumped solid state laser of claim 8, wherein said side frame member is comprised of an electrically isolating material.

10. The side-pumped solid state laser of claim 9, wherein said electrically isolating material is selected from the group consisting of aluminum nitride, beryllium oxide, CVD diamond and silicon carbide.

11. The side-pumped solid state laser of claim 4, further comprising:
a backplane member interposed between a back surface of each submount of said plurality of laser diode submount assemblies and said cooling block;
a first side frame member interposed between a first side surface of each submount of said plurality of laser diode submount assemblies and said cooling block; and
a second side frame member interposed between a second side surface of each submount of said plurality of laser diode submount assemblies and said cooling block.

12. The side-pumped solid state laser of claim 4, wherein said cooling block is comprised of a first member and a second member, wherein said first and second cooling block members form a slotted region, and wherein said plurality of laser diode submount assemblies fit within said slotted region.

13. The side-pumped solid state laser of claim 1, wherein each submount of said plurality of laser diode submount assemblies is comprised of an electrically conductive material.

14. The side-pumped solid state laser of claim 13, wherein said electrically conductive material is selected from the group consisting of copper, copper tungsten, copper molybdenum, matrix metal composites and carbon composites.

15. The side-pumped solid state laser of claim 1, further comprising a solder layer interposed between each of said at least one laser diode and said first portion of said first surface of each submount of said plurality of laser diode submount assemblies.

16. The side-pumped solid state laser of claim 1, said spacer further comprising an electrical isolator attached to said second portion of said first surface of said submount and an electrical contact pad attached to said electrical isolator.

17. The side-pumped solid state laser of claim 16, further comprising a metallization layer deposited on a top surface of said electrical isolator of each of said plurality of laser diode submount assemblies, wherein said electrical contact pad is in electrical communication with said metallization layer.

18. The side-pumped solid state laser of claim 17, further comprising at least one wire bond coupling said at least one laser diode and said metallization layer of each of said plurality of laser diode submount assemblies.

19. The side-pumped solid state laser of claim 17, further comprising at least one ribbon bond coupling said at least one laser diode and said metallization layer of each of said plurality of laser diode submount assemblies.

20. The side-pumped solid state laser of claim 16, wherein said mechanically coupling means further comprises means for electrically connecting each electrical contact pad to said second surface of said submount of said adjacent laser diode submount assembly.

21. The side-pumped solid state laser of claim 20, wherein said electrically connecting means is comprised of a solder layer.

22. The side-pumped solid state laser of claim 1, wherein the fast axis of each laser diode is co-aligned with the fast axis of a corresponding laser diode on said adjacent laser diode submount assembly.

23. The side-pumped solid state laser of claim 1, wherein said at least one laser diode of said plurality of laser diode submount assemblies is a single mode single emitter laser diode.

24. The side-pumped solid state laser of claim 1, wherein said at least one laser diode of said plurality of laser diode submount assemblies is a broad area multi-mode single emitter laser diode.

25. The side-pumped solid state laser of claim 1, wherein said at least one laser diode of said plurality of laser diode submount assemblies is comprised of multiple single emitters on multiple substrates.

26. The side-pumped solid state laser of claim 1, wherein said at least one laser diode of said plurality of laser diode submount assemblies is comprised of multiple single emitters on a single substrate.

27. The side-pumped solid state laser of claim 1, wherein each of said at least one laser diodes of each of said at least two laser diode subassemblies is individually addressable.

28. The side-pumped solid state laser of claim 1, wherein said output beams from said radiation-emitting active layers of said laser diodes of said plurality of laser diode submount assemblies include at least a first wavelength and a second wavelength.

29. The side-pumped solid state laser of claim 28, wherein a first plurality of said laser diode submount assemblies produce said first wavelength and a second plurality of said laser diode submount assemblies produce said second wavelength.

30. The side-pumped solid state laser of claim 29, wherein said first and second pluralities of said laser diode submount assemblies alternate in position within said laser diode stack.

31. The side-pumped solid state laser of claim 28, wherein each laser diode attached to each submount of each of said plurality of laser diode submount assemblies is comprised of multiple single emitters, wherein a first plurality of said multiple single emitters produce said first wavelength and a second plurality of said multiple single emitters produce said second wavelength.

32. The side-pumped solid state laser of claim 31, wherein said first and second pluralities of multiple single emitters are fabricated on individual substrates.
